(19) United States
(12) Patent Application Publication
(10) Pub. No.: US 2005/0211550 A1
(43) Pub. Date: Sep. 29, 2005

(54) Device for reactive sputtering

(76) Inventors: Thomas Fritz, Freigericht (DE); Gunter Kemmerer, Alzenau (DE)

Correspondence Address: FULBRIGHT & JAWORSKI, LLP, 666 FIFTH AVE, NEW YORK, NY, 10103-3198, US

(21) Appl. No.: 10/918,749

(22) Filed: Aug. 12, 2004

(30) Foreign Application Priority Data
Mar. 26, 2004 (DE) 10 2004 014 855.4

(51) Int. Cl. C23C 14/34

(52) U.S. Cl. 204/192.13; 204/298.07; 204/298.03

(57) ABSTRACT

A device for reactive sputtering, wherein a cathode is applied a discharge voltage for a plasma, and a working gas and a reactive gas are introduced into a sputter chamber. The total gas flow in the sputter chamber is controlled with the aid of a valve, while the ratio of the partial pressures of both gases is kept constant.

This application claims priority from German Patent Application No: 10 2004 014 855.4 filed Mar. 26, 2004 which is incorporated herein by reference in its entirety.

### BACKGROUND AND SUMMARY OF THE INVENTION

The invention relates in part to a device for reactive sputtering.

In reactive sputtering, as a rule, at least two gases are employed: one gas, which most often is inert and which in the ionized form knocks particles out of a target, and a reactive gas, which forms a compound with the knocked-out particles. This compound is subsequently deposited as a thin layer on a substrate, for example a glass sheet.

In order for ions of an inert gas to be accelerated onto a target, an electric voltage must be applied to this target. This voltage between the target and an antipole depends inter alia on the gas pressure which obtains in a sputter chamber. If an electrically nonconducting substrate to be coated is moved through a sputter chamber, the voltage can additionally also depend on the particular location of the substrate.

The dependence of the voltage on the pressure can be explained thereby that at higher pressure there are still atoms in the gas volume, such that more charge carriers are also generated. At the same electric power hereby a higher discharge current flows and the voltage decreases.

The dependence of the voltage on the location of the substrate can be explained as follows:
If the electrically nonconducting substrate is moved past underneath the sputter cathode with the target, the substrate covers increasingly more anode volume beneath the target. Hereby the anode becomes smaller, which is why at the same power the anode voltage must be increased in order to draw the required current.

The plasma is additionally also affected through a contamination effect, which occurs thereby that reactive products become deposited on the target.

If the reactive product emits more secondary electrons than the metallic target, the fraction of the electrically charged particles of the plasma is increased. Hereby the plasma impedance decreases, such that at constant electric power an increased current flows at lower voltage. This effect is enhanced if the fraction of reactive gases is increased relative to the inert gas.

If for example aluminum targets are sputtered in an oxygen-containing atmosphere, the resulting aluminum oxide has an emission of secondary electrons which, in comparison to the metallic aluminum, is increased seven-fold. On the other hand, the sputter rate of the reactive product is most often lower than that of the pure metal.

As a consequence of the above described effect, the discharge voltage decreases with increasing reactive fractions and, at identical power, a higher current flows at lower voltage.

A sputter coating installation is already known, which comprises a regulation with which the cathode power can be set to a specified operating value (DE 101 35 761 A1, EP 1 197 578 A2). In addition to the cathode power, the gas flow of the reactive gas is also regulated with the aid of a fuzzy logic system.

Moreover, a sputter coating installation is known which includes a regulation circuit, which acquires the measured value specifying the cathode voltage as well as the measured value specifying the voltage drops, which as a function of these measured values controls the gas flow of the reactive gas based on a fuzzy logic system (DE 101 35 802 A1).

The invention addresses the problem of keeping the cathode voltage of a reactive coating installation constant while simultaneously maintaining a uniformly high coating rate.

This problem is solved according to the present invention.

Consequently, the invention relates to a device for reactive sputtering, in which to a cathode is applied a discharge voltage for a plasma, and a working gas and a reactive gas are introduced into a sputter chamber. The total gas flow in the sputter chamber is controlled with the aid of a valve, while the ratio of the partial pressures of the two gases is kept constant.

One advantage attained with the invention comprises that the discharge voltage can also be kept constant if during an inline operation a change of the voltage relation is effected through the successive substrates.

An embodiment example of the invention is shown in the drawing and will be explained in further detail in the following. In the drawing depict:

### BRIEF DESCRIPTION OF THE FIGURES

FIG. 1 is a sputter installation according to the invention,

FIG. 2 is a first relationship between cathode voltage and reactive gas flow,

FIG. 3 is a second relationship between cathode voltage and reactive gas flow,

FIG. 4 is a relationship between the location of a substrate moved past a sputter cathode and the cathode voltage.

### DETAILED DESCRIPTION

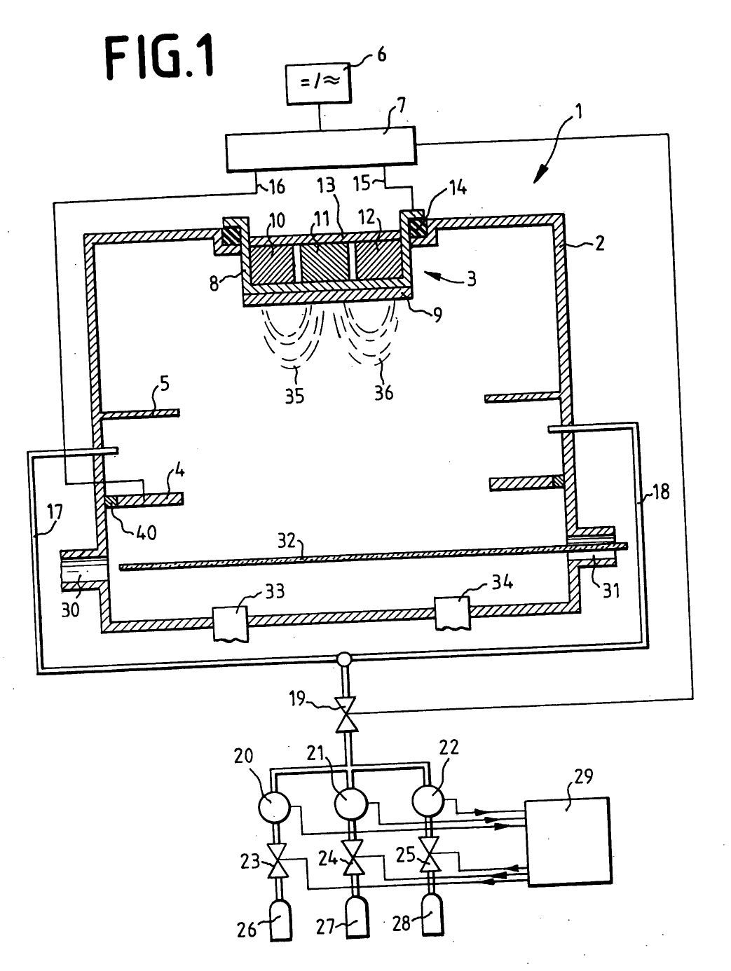

FIG. 1 depicts the principle of a sputter installation 1, which comprises a sputter chamber 2, a cathode 3, an anode 4, a shielding 5, a voltage source 6 and a regulation circuit 7. The cathode 3 comprises a tub-form cathode part 8, onto which a target 9 to be sputtered is flanged. In the tub-form cathode part 8 are disposed three permanent magnets 10, 11, 12, which are connected with one another across a yoke 13.

The cathode part 8 rests via a seal 14 on a margin of an opening in the sputter chamber 2. The voltage of the voltage source 6 is conducted via the regulation circuit 7 with its one pole 15 to the cathode part 8 and with its other pole 16 to the anode 4. The regulation circuit 7 keeps the voltage output to the anode-cathode path constant even if the voltage of the voltage source 6 fluctuates. The fluctuation of the discharge voltage is effected substantially through the passing substrate. Keeping the voltage constant is attained thereby that the total gas flow, conducted via gas lines 17, 18, into the sputter chamber 2, is regulated by means of a regulatable valve 19. The partial pressures of different gases always retain herein the same ratio. This is attained through a configuration which comprises, for example, three pressure sensors 20, 21, 22 and three controllable valves 23, 24, 25, with which the particular pressure of a gas from a gas cylinder 26, 27, 28 can be regulated. The ratio of the partial pressures of the gases is always kept constant with a regulation circuit 29. This regulation circuit 29 can also be integrated into the regulation circuit 7.

Beneath the anode 4 in the sputter chamber 2 are provided two openings 30, 31, through which a plate 32 to be coated can be pushed, for example, from the left to the right. Beneath the plate 32 are disposed two evacuation ports 33, 34, which are connected with (not shown) pumps, with which a quasi-vacuum can be generated in the sputter chamber 2. By 35, 36 are denoted plasma clouds which spread in the form of arches in front of the target 9.

The gas cylinder 26 can contain for example inert gas, while in the gas cylinders 27 and 28 different reactive gases are contained.

The valve 19 can be a butterfly valve. The structure of such a butterfly valve corresponds to the throttle valve of a carburetor. A disk adapted in its cross sectional area to the encompassing tube is supported rotatably about its axis of symmetry. Depending on the set angle of the disk with respect to the cross section of the tube, a greater or lesser amount of the area of the cross section of the tube is cleared. In the 90 degree position the greatest evacuation opening is obtained, in the 0 degree position the evacuation opening is closed.

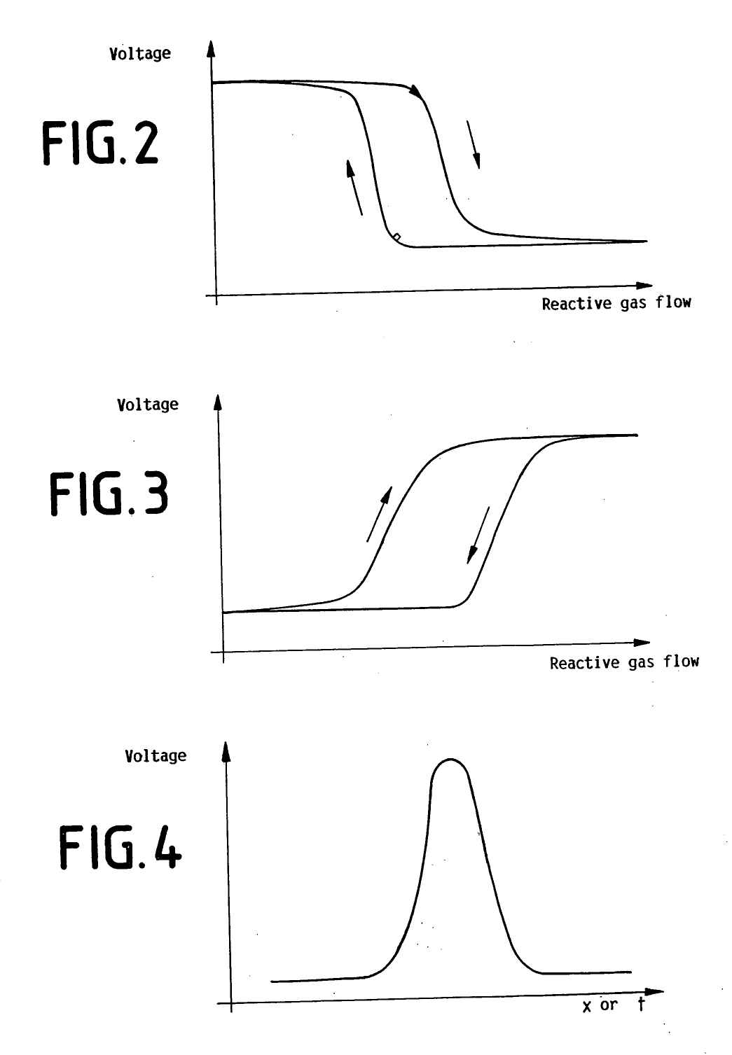

FIG. 2 represents the relationship between cathode voltage and reactive gas flow. It is evident that the curve which represents this relationship, has a hysteresis. It can be seen that with increasing reactive gas fraction the discharge voltage decreases. Consequently, at the same power a higher current flows at lower voltage.

Starting at a certain point, which in the curve of FIG. 2 is marked with a triangle, the sputtering surface of the target is coated with reactive product to the extent that, due to the low sputter rate of the reactive product, the quantity of reactive gas for the pure metal sputtering with reduced surface fraction is too high, such that the target surface is completely coated with the reactive product. Above this point, a metastable working point is possible which is marked with the triangle. Further particulars regarding the hysteresis effect can be found, for example, in FIG. 1 and 2 of U.S. Pat. No. 6,511,584.

The hysteresis depicted in FIG. 2 depends on the particular combination of target material and reactive gas. There are also hysteresis curves, which run mirror-symmetrically to the hysteresis curves according to FIG. 2. Such a hysteresis curve is depicted in FIG. 3. It is possible to vary the reactive gas flow at constant inert gas flow or to adapt the inert gas flow at constant reactive gas flow. Simplified, it is conceivable that the inert gas primarily as working gas erodes the target material, while the reactive gas is mainly required for the chemical reaction.

The issue in the present invention is keeping constant the discharge voltage of the cathode or the cathodes in an installation with at least one sputter cathode, which is encompassed by an anode and a shielding.

The substrate 32 to be coated is closely followed by a second (not shown in FIG. 1) substrate, such that between both substrates a spacing is formed. The evacuation capacity of the pumps connected to the ports 33, 34, is thereby impaired, i.e. the evacuation capacity fluctuates. The cross section of the openings of the ports 33, 34, through which the gas is pumped from the sputter chamber 2, is increasingly covered by the substrate 32 moving toward the right, until it is only possible to pump out via the narrow gap between anode 4 and between two successive substrates. Due to the movement of the substrate 32, the evacuation capacity decreases from a maximum value to a minimum value. If the gas delivery remains constant, the pressure in the volume in front of the cathode 3 increases. But, depending on the reactive process, the increasing pressure leads to a decrease or an increase of the discharge voltage. In this case a voltage curve results, as is shown in FIG. 4, which depends on the position of the substrate. If the substrate, which had covered the evacuation port, and therewith caused a change of the evacuation conductance, again clears the evacuation cross section, the discharge voltage assumes again the original value. Instead of the spatial coordinate x, it is also possible to specify in FIG. 4 the time coordinate, since the position is a function of the time via the relationship υ=x/t.

This voltage change due to the covering of the evacuation cross section is counteracted according to the invention by regulation of the gas flow.

The voltage at the cathode and the gas pressure are important parameters for setting layer properties, such as for example of mechanical stresses in the deposited layers, which, for example, can be the reason for a flexible substrate to become rolled up or for the layer to become torn from the substrate and becoming rolled up. Via these parameters the layer growth of the deposited layers can be affected, such as for example the surface roughness, the electric layer resistance, or a layer structure which is more stem-like or similar to the bulk material, the porosity, degree of crystallinity and the like.

The voltage regulation employed here is not the voltage regulation conventionally used in sputter technique. This conventional voltage regulation is a regulation variant for a sputter power supply, whose output voltage is kept constant, and specifically in contrast to a current or power regulation, in which the current or the power are kept constant.

The relationship between keeping constant the voltage and the regulation of the pressure at constant partial pressure ratio is complex. In a first approximation, the sputter power is actually proportional to the sputter rate. The sputter rate indicates the quantity of the target material eroded which subsequently reacts with the reactive gas. The ratio of eroded material to the reactive gas must be kept constant, in order for the same reactive product to be formed; stated differently, the sputter power would actually need to be kept constant with the gas pressure.

Also as an approximation applies that, apart from the electric power, the inert gas fraction of the process gas mixture as the working gas is responsible for the sputter rate, and the reactive gas fraction determines the chemical reaction. For that reason the partial pressure ratio must be kept constant.

On the other hand, it is known that the sputter voltage has an effect on the layer growth, and consequently on the layer properties, such that it is reasonable to keep the voltage constant. It is probable that several effects are superimposed on one another such that they compensate one another and there is no measurable difference whether the voltage or the power is kept constant. If, for example, in the proposed regulation the current of the sputter discharge changes only minimally within the required regulation range, thus as a first approximation is constant, and, on the other hand, the voltage is kept constant, the sputter power, and therewith also the sputter rate, remains constant.

The degree to which at constant voltage the current of the discharge changes as a function of the pressure, is inter alia also determined by the current-voltage characteristics as well as the voltage-pressure characteristic. Both are device properties depending on the structure of the magnetrons utilized.

1-8. (canceled)

9. A device for reactive sputtering, comprising:
at least one cathode to which is applied a discharge voltage for a plasma;
at least one working gas and at least one reactive gas in a sputter chamber;
a controllable valve with which total gas flow into the sputter chamber can be controlled; and
a regulation circuit, with which the ratio of partial pressures of the at least one working gas and at least one reactive gas is kept constant.

10. A device as claimed in claim 9, wherein at a spacing from the cathode a substrate to be worked can be moved past the cathode.

11. A device as claimed in claim 9, wherein evacuation ports for the gas in the sputter chamber are provided beneath the substrate to be worked.

12. A device as claimed in claim 9, further comprising several gas containers, each of which is provided with a controllable valve, the gases controlled by the valves being supplied to a common gas line.

13. A device as claimed in claim 9, further comprising pressure sensors that measure the pressure of the gases let through by the valves.

14. A device as claimed in claim 9, further comprising a shield between a substrate and said at least one cathode.

15. A device as claimed in claim 9, wherein the working gas is argon.

16. A method for the regulation of the discharge voltage during reactive sputtering in an inline installation, comprising moving several area substrates sequentially through a sputter chamber so that between two area substrates a gap is formed, and regulating the discharge voltage by varying a total gas stream.
